(19) United States
(12) Patent Application Publication
(10) Pub. No.: US 2014/0170796 A1
(43) Pub. Date: Jun. 19, 2014

(54) IMAGE SENSOR PACKAGING METHOD

(71) Applicant: STACK DEVICES CORP., Chunan Miaoli (TW)

(72) Inventors: Mon-Nan HO, Chunan Miaoli (TW); Chien-Heng LIN, Chunan Miaoli (TW); Ching-Shui CHENG, Chunan Miaoli (TW); Po-Wen CHOU, Chunan Miaoli (TW)

(73) Assignee: STACK DEVICES CORP., Chunan Miaoli (TW)

(21) Appl. No.: 13/717,002

(22) Filed: Dec. 17, 2012

(51) Int. Cl. H01L 31/18

(52) U.S. Cl. CPC H01L 31/18
USPC 438/65

(57) ABSTRACT

A image sensor packaging method includes the steps of: a) installing an image sensor chip in a circuit substrate and then covering a light transmissive cover on the image sensor chip over a sensing zone of the image sensor chip and then covering a passivation layer on the light transmissive cover, b) using a plurality of lead wires to connect respective conducting contacts of the circuit substrate to respective conducting contacts of the image sensor chip, c) molding an encapsulation on the circuit substrate and the image sensor chip to wrap the lead wires, and d) removing the passivation layer.

Thus, the light transmissive cover and the passivation layer protect the sensing zone of the image sensor chip and the light transmissive cover against contamination and damage, and therefore, this image sensor chip packaging method has high-yield performance.

### BACKGROUND OF THE INVENTION

1. Field of the Invention

The present invention relates to image sensor packaging technology and more particularly, to an image sensor chip protective image sensor packaging method for packaging image sensor package structures.

2. Description of the Related Art

Referring to FIG. 1, a conventional image sensor packaging method is known comprising the step of bonding a CCD (charge coupled device) or CMOS (complementary metal-oxide-semiconductor) image sensor chip 10 to a circuit substrate 11 and then soldering lead wires 12 to connect respective conducting contacts of the image sensor chip 10 to respective conducting contacts of the circuit substrate 11, and the step of molding an encapsulation 13 of a special packaging material on the circuit substrate 11 and the image sensor chip 10 using a compression molding technique and then bonding a glass plate 14 to the image sensor chip 10 over a sensing zone 15 of the image sensor chip 10. Thus, the lead wires 12 are embedded in the encapsulation 13 and will not break easily under the protection of the encapsulation 13. Further, the sensing zone 15 of the image sensor chip 10 is protected by the glass plate 14 and adapted to sense images outside the glass plate 14.

However, according to the aforesaid prior art image sensor packaging method, the sensing zone 15 of the image sensor chip 10 tends to be contaminated or damaged during the packaging process, affecting the quality of the image sensor and leading to low yield.

### SUMMARY OF THE INVENTION

The present invention has been accomplished under the circumstances in view. It is one object of the present invention to provide an image sensor packaging method for packaging image sensor package structures, which protects the sensing zone of the image sensor chip against contamination and damage during the packaging process, achieving high-yield performance.

To achieve this and other objects of the present invention, an image sensor packaging method comprises the steps of: a) installing an image sensor chip in a circuit substrate and then covering a light transmissive cover on the image sensor chip over a sensing zone of the image sensor chip and then covering a passivation layer on the light transmissive cover, b) using a plurality of lead wires to connect respective conducting contacts of the circuit substrate to respective conducting contacts of the image sensor chip, c) molding an encapsulation on the circuit substrate and the image sensor chip to wrap the lead wires, and d) removing the passivation layer.

Thus, during step b) and step c), the light transmissive cover protects then sensing zone of the image sensor chip and the passivation layer protects the light transmissive cover to against contamination and damage, and therefore, this image sensor chip packaging method has high-yield performance.

Other advantages and features of the present invention will be fully understood by reference to the following specification in conjunction with the accompanying drawings, in which like reference signs denote like components of structure.

### BRIEF DESCRIPTION OF THE DRAWING

FIG. 1 is a schematic drawing illustrating an image sensor package structure made according to the prior art.

FIG. 2 is schematic drawing illustrating the packaging process of an image sensor packaging method in accordance with a first embodiment of the present invention (I).

FIG. 3 is schematic drawing illustrating the packaging process of the image sensor packaging method in accordance with the first embodiment of the present invention (II). FIG. 4 is schematic drawing illustrating the packaging process of the image sensor packaging method in accordance with the first embodiment of the present invention (III).

FIG. 5 is schematic drawing illustrating the packaging process of the image sensor packaging method in accordance with the first embodiment of the present invention (IV).

FIG. 6 is schematic drawing illustrating the packaging process of the image sensor packaging method in accordance with the first embodiment of the present invention (V).

FIG. 7 is schematic drawing illustrating the packaging process of the image sensor packaging method in accordance with the first embodiment of the present invention (VI).

FIG. 8 is schematic drawing illustrating an alternate form of the packaging process of the image sensor packaging method in accordance with the first embodiment of the present invention.

FIG. 9 is schematic drawing illustrating the packaging process of the image sensor packaging method in accordance with a second embodiment of the present invention (I).

FIG. 10 is schematic drawing illustrating the packaging process of the image sensor packaging method in accordance with the second embodiment of the present invention (II).

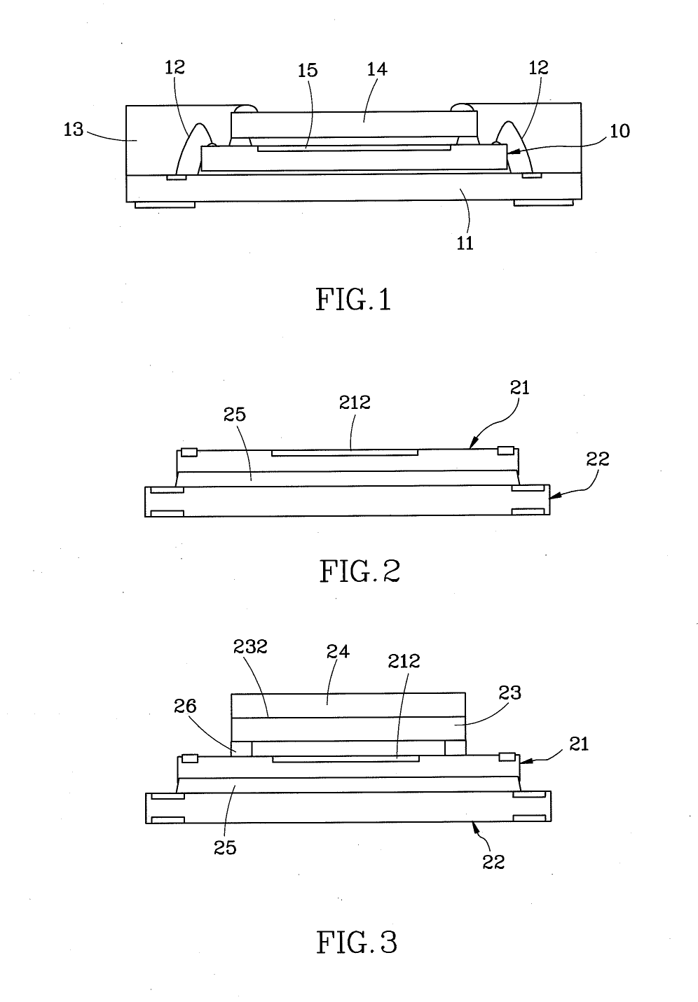

### DETAILED DESCRIPTION OF THE PREFERRED EMBODIMENT

Before describing the present invention, it is to be understood that like reference numerals throughout the drawings denote like component parts.

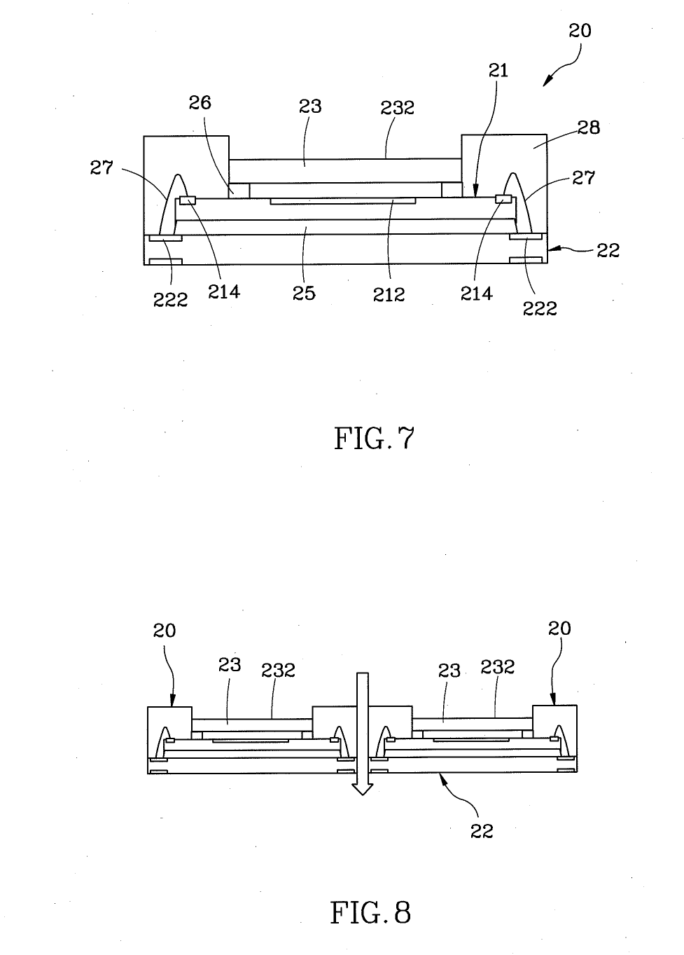

Referring to FIGS. 2-7, a image sensor packaging method in accordance with a first embodiment of the present invention is to package an image sensor package structure 20 (see FIG. 7). This image sensor packaging method comprises the steps outlined hereinafter.

a) As shown in FIGS. 2 and 3, install an image sensor chip 21 in a circuit substrate 22, and then cover a light transmissive cover 23 on the image sensor chip 21 over a sensing zone 212 of the image sensor chip 21, and then cover a passivation layer 24 over the top wall 232 of the light transmissive cover 23. In this embodiment, the light transmissive cover 23 is a glass plate of excellent light transmission. The passivation layer 24 is a layer of a special liquid material (for example, acrylic acid) printed or transfer-printed on the top wall 232 of the light transmissive cover 23. By means of printing or transfer-printing technology, the passivation layer can be quickly coated on the light transmissive cover 23, facilitating mass production.

In this embodiment, the image sensor chip 21 is bonded to the circuit substrate 22 by an adhesive 25, and then the light transmissive cover 23 is bonded to the image sensor chip 21 by an adhesive 26, and then the passivation layer 24 is covered on the top wall 232 of the light transmissive cover 23. Further, the area of the passivation layer 24 is larger than the area of the sensing zone 212 and equal to the area of the top wall 232 of the light transmissive cover 23. Alternatively, the image sensor chip 21 can be bonded to the circuit substrate 22 after the installation of the light transmissive cover 23; the passivation layer 24 can be covered on the top wall 232 of the light transmissive cover 23 prior to the mounting of the light transmissive cover 23 at the image sensor chip 21; the area of the passivation layer 24 can be smaller than the area of the top wall 232 of the light transmissive cover 23.

b) As shown in FIG. 4, use a plurality of lead wires 27 to connect respective conducting contacts 222 at the circuit substrate 22 and respective conducting contacts 214 at the image sensor chip 21.

There is no limitation to the amount of the lead wires 27. The amount of the lead wires 27 can be determined subject to actual requirements. This step is same as the prior art technique. However, the arrangement of the passivation layer 23 can protect the sensing zone 212 of the image sensor chip 21 against contamination or damage, and the passivation layer 24 can protect the top wall 232 of the light transmissive cover 23 against contamination or damage.

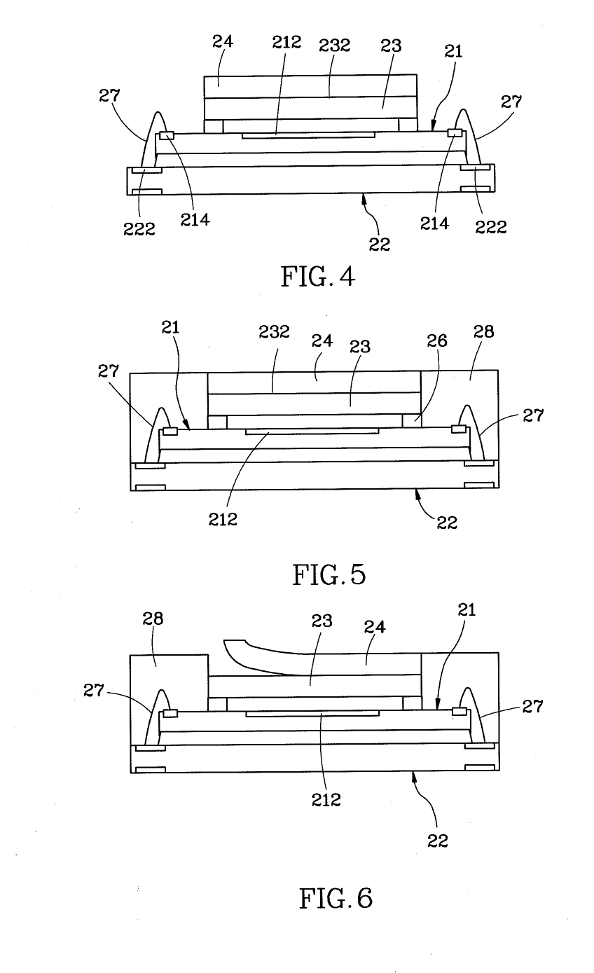

c) As shown in FIG. 5, mold an encapsulation 28 on the circuit substrate 22 and the image sensor chip 21 to wrap the lead wires 27.

The encapsulation 28 is formed of a special packaging material using a compression molding technique, and adapted to protect the lead wires 27, avoiding lead wire breaking. The light transmissive cover 23 and the passivation layer 24 can protect the sensing zone 212 of the image sensor chip 21 and the top wall 232 of the light transmissive cover 23 against contamination or damage during this step. Further, in this embodiment, the encapsulation 28 and the passivation layer 24 have the same height. Thus, the passivation layer 24 provides a buffer effect during compression molding of the encapsulation 28. However, the passivation layer 24 can also provide a buffer effect if it is higher than the encapsulation 28.

d) As shown in FIG. 6, remove the passivation layer 24. After removal of the passivation layer 24, the sensing zone 212 of the image sensor chip 21 can sense images outside the light transmissive cover 23.

In the aforesaid image sensor packaging method, the sensing zone 212 of the image sensor chip 21 and the top wall 232 of the light transmissive cover 23 are well protected against contamination or damage. Therefore, this image sensor packing method achieves high-yield performance.

It's worth mentioning that in actual application, the image sensor chip packaging method of the present invention is to produce a plurality of package structures 20 using one common said circuit substrate 22 at a time, and these package structures 20 are separated using a cutting technique (see FIG. 8). However, this cutting technique can be performed prior to step d), avoiding contamination of the sensing zone 212 of the image sensor chip 21 during cutting.

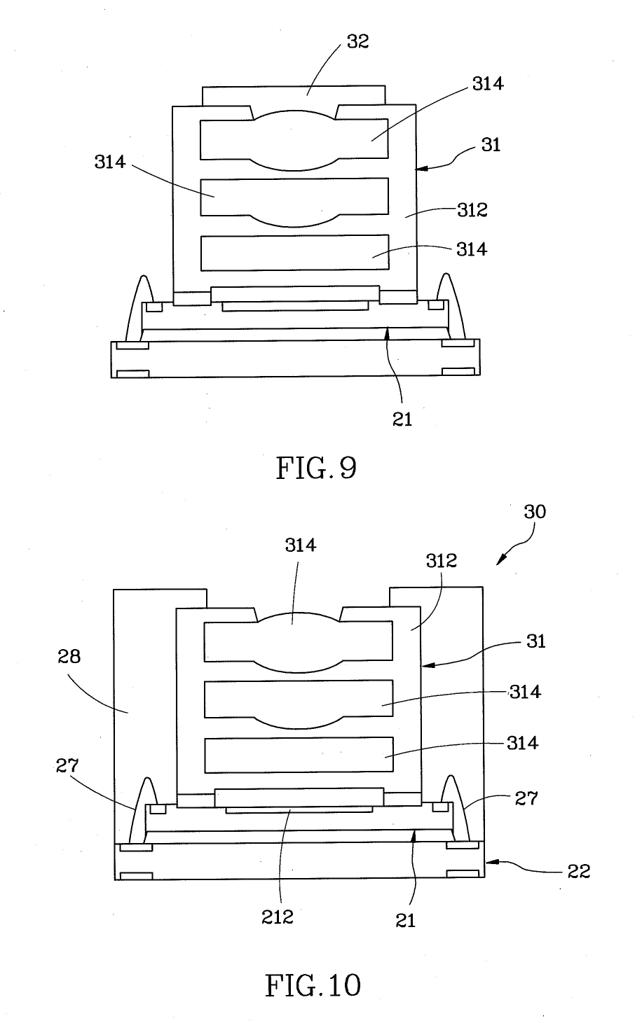

Referring to FIGS. 9 and 10, an image sensor package structure 30 made in accordance with a second embodiment of the present invention is shown. When compared to the image sensor package structure 20 made in accordance with the first embodiment of the present invention (see FIG. 7), the light transmissive cover 31 of the image sensor package structure 30 (see FIG. 10) is a camera lens assembly comprising a lens barrel 312 and a plurality of lenses 314 mounted in the lens barrel 312. The image sensor packing method of this second embodiment comprises the step of: a) (see FIG. 9) bonding the lens barrel 312 to the image sensor chip 21 and then covering a passivation layer 32 on a top wall of the lens barrel 312 and a top wall of one said lens 314. After step a), performs steps b) through d) that are same as the aforesaid first embodiment and then perform the cutting step. Thus, when the image sensor package structure 30 is mounted in a mobile electronic device, such as camera, cell phone, notebook computer or the like, the mobile electronic device provides an image sensor chip and a camera lens assembly, and no further camera lens means is necessary.

In actual application, the light transmissive cover used during the application of the image sensor packaging method is not limited to a glass plate or camera lens assembly. The light transmissive cover can be made of any other suitable material or structure that admits light and allows the sensing zone of the image sensor chip to sense images outside the light transmissive cover.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. An image sensor packaging method, comprising:
a) installing an image sensor chip in a circuit substrate and then covering a light transmissive cover on said image sensor chip over a sensing zone of said image sensor chip and then covering a passivation layer on said light transmissive cover;
b) using a plurality of lead wires to connect respective conducting contacts of said circuit substrate to respective conducting contacts of said image sensor chip;
c) molding an encapsulation on said circuit substrate and said image sensor chip to wrap said lead wires; and
d) removing said passivation layer.

2. The image sensor packaging method as claimed in claim 1, wherein the area of said passivation layer is larger than the area of said sensing zone of said image sensor chip and smaller or equal to the area of the top wall of said light transmissive cover.

3. The image sensor packaging method as claimed in claim 1, wherein during step c), said encapsulation is kept equal to or lower than the elevation of said passivation layer.

4. The image sensor packaging method as claimed in claim 1, wherein said light transmissive cover is a glass plate.

5. The image sensor packaging method as claimed in claim 4, wherein said passivation layer is covered on a top wall of said light transmissive cover.

6. The image sensor packaging method as claimed in claim 1, wherein said light transmissive cover is a camera lens means.

7. The image sensor packaging method as claimed in claim 1, wherein said passivation layer is covered on a top wall of said lens barrel and a top wall of one said lens.
